(19) United States
(12) Patent Application Publication
(10) Pub. No.: US 2004/0238877 A1
(43) Pub. Date: Dec. 2, 2004

(54) Electrically programmable and erasable memory cell having an improved floating gate and a method of manufacturing said floating gate and a memory device having an array of such cells made thereby

(76) Inventors: Sreeni Maheshwarla, Sunnyvale, CA (US); Pavel Klinger, San Jose, CA (US)

Correspondence Address: Ronald L. Yin, Gray Cary Ware & Freidenrich, 1755 Embarcadero Road, Palo Alto, CA, 94303, US

(21) Appl. No.: 10/452,016

(22) Filed: May 30, 2003

(51) Int. Cl. H01L 29/788

(52) U.S. Cl. 257/315

(57) ABSTRACT

An electrically programmable and erasable memory cell and an array of such memory cells have a semiconductor substrate of a first conductivity type. A first and second regions of a second conductivity type are in the substrate, spaced apart from one another. A channel region is formed between the first region and the second region for the conduction of charges. A floating gate is on a portion of the channel and insulated therefrom. The floating gate has a length in the channel direction with a first end and a second end with a tip located between the first end and the second end. A control gate is spaced apart from the floating gate by an insulation layer with the control gate having a portion aligned with the tip to receive charges emitted from the tip of the floating gate.

### TECHNICAL FIELD

The present invention relates to an electrically programmable and erasable memory cell with an improved floating gate having an improved injector tip. More particularly, the present invention relates to such a floating gate having a first end and a second end wherein the injector tip is located between the first end and the second end.

### BACKGROUND OF THE INVENTION

The formation of a tip in a floating gate wherein the tip is used during erase operation for poly to poly Fowler-Nordheim tunneling is well known in the art. See, for example, U.S. Pat. No. 5,029,130, whose disclosure is incorporated herein by reference in its entirety, for a discussion of the operation of a non-volatile memory cell having source side injection and programming via hot channel electron injection and erase by poly to poly Fowler-Nordheim tunneling. The tip on the floating gate serves to improve the mechanism of Fowler-Nordheim tunneling from the floating gate to a control gate.

Referring to FIGS. 1A-1E and FIGS. 2A-20, there is shown various views of a process of the prior art to make a non-volatile memory cell having a floating gate with a “tip” thereon.

In particular, FIGS. 1A-1E illustrate the well known STI method of forming isolation regions on a substrate. Referring to FIG. 1A, there is shown a top plan view of a semiconductor substrate 10 (or a semiconductor well), which is preferable of P-type and is well known in the art. A first layer 11 of silicon dioxide (hereinafter “oxide”) is formed (e.g. grown or deposited) on the substrate 10 by any well known technique such as oxidation or oxide deposition (e.g. chemical vapor deposition or CVD) to a thickness of approximately 50-120 angstroms. A second layer of polysilicon 12 is formed (e.g. grown or deposited) on the oxide 11. Finally, a third layer of silicon nitride (hereinafter “nitride”) 14 is formed over polysilicon layer 12 preferably by CVD to a thickness of approximately 1000 to 3000 angstroms. FIG. 1B illustrates a cross-section of the resulting structure.

Once the first, second and third layers 11/12/14 have been formed, suitable photo resist material 16 is applied on the nitride layer 14 and a masking step is performed to selectively remove the photo resist material 16 from certain regions (stripes 18) that extend in the Y or column direction, as shown in FIG. 1C. Where the photo-resist material 16 is removed, the exposed nitride layer 14, polysilicon layer 12, and oxide layer 11 are etched away in stripes 18 using standard etching techniques (i.e. anisotropic nitride, polysilicon, and oxide etch processes) to form trenches 20 in the structure. The distance W between adjacent stripes 18 can be as small as the smallest lithographic feature of the process used. A silicon etch process is then used to extend trenches 20 down into the silicon substrate 10, as shown in FIG. 1D. Where the photo resist 16 is not removed, the nitride layer 14, polysilicon layer 12 and oxide layer 11 are maintained. The resulting structure illustrated in FIG. 1D now defines active regions 22 interlaced with isolation regions 24.

The structure is further processed to remove the remaining photo resist 16. Then, an isolation material such as silicon dioxide is formed in trenches 20 by depositing a thick oxide layer, followed by a Chemical-Mechanical-Polishing or CMP etch (using nitride layer 14 as an etch stop) to remove the oxide layer except for oxide blocks 26 in trenches 20, as shown in FIG. 1E.

FIGS. 1A to 1E illustrate the memory cell array region of the substrate, in which columns of memory cells will be formed in the active regions 22 which are separated by the isolation regions 24. It should be noted that the substrate 10 also includes at least one periphery region in which control circuitry is formed that will be used to operate the memory cells formed in the memory cell array region. Preferably, isolation blocks 26 are also formed in the periphery region during the same STI process described above.

The structure shown in FIG. 1E is further processed as follows. FIGS. 2A-20 show the cross-section views of a portion of the structure in the active regions 22 from a view orthogonal to that of FIG. 1E (along line 2A-2A as shown in FIG. 1C), showing two adjacent memory cells. FIG. 2A is a cross-sectional view of the structure shown in FIG. 1E taking along the line 2A-2A in the memory cell array portion.

Photoresist 15 is then applied everywhere. A masking step is performed wherein strips extending in the X direction, of the photoresist 15 are removed. The resultant structure is shown in FIG. 2B.

With the photoresist 15 as a mask, an anisotropic etch of the nitride 14 is then made. The polysilicon 12 is used as an etch stop. The photoresist 15 is then removed. The resultant structure is shown in FIG. 2C.

The structure shown in FIG. 2C is then subject to a partial polysilicon etch. The polysilicon 12 near the boundary with the nitride layers 14 will not be etched in a straight line. Instead, a sloped line is formed. The resultant structure is shown in FIG. 2D.

The structure shown in FIG. 2D is then subject to an oxidation step. This oxidizes the exposed region of polysilicon 12 to form a second oxide layer 16 with the oxide layer 16 “on top” of the polysilicon layer 12. The resultant structure is shown in FIG. 2E.

An oxide layer 18 is deposited everywhere using the TEOS process. The resultant structure is shown in FIG. 2F.

The structure shown in FIG. 2F is then subject to an anisotropic oxide etch of the layer oxide 18 with polysilicon 12 used as an etch stop. The result of this process is the formation of spacers of TEOS oxide 18 around the nitride 14. This is shown in FIG. 2G.

The structure shown in FIG. 2G is then subject to an anisotropic etch of the polysilicon 12. The anisotropic etch of the polysilicon 12 is a complete anisotropic etch using the oxide layer 11 as an etch stop. The resultant structure is shown in FIG. 2H.

A thin layer of oxide (on the order of 200-600 angstroms) is deposited on the structure shown in FIG. 2H. The thin oxide is then anisotropically etched, resulting in a thin oxide spacer formed adjacent to the polysilicon 12. The etching of the thin oxide layer using anisotropical etch serves to completely etch the oxide layer 11, with the substrate 10 used as an etch stop. The resultant structure is shown in FIG. 21.

Ion implantation is performed on the structure shown in FIG. 21 to form the source regions in the substrate 10 adjacent to the oxide spacers 18. If the substrate is P type, the source regions would be N type. Polysilicon 20 is then deposited everywhere. Since the structure shown in FIG. 21 is a portion of a “regular” memory array, the pattern shown in FIG. 21 is repeated. As a result, polysilicon 20 would be deposited adjacent to the oxide 18, and on top of the nitride 14. The structure with the polysilicon 20 is then anisotropically etched until all of the polysilicon 20 is removed from “on top” of the nitride 14 and remains only in the region between adjacent structures of oxide spacers 18. Finally, the polysilicon 20 is then oxidized to form the oxide layer 22. As a result, the polysilicon 20 “connects” the source regions in the substrate 10 in the X direction. The resultant structure is shown in FIG. 2J.

The nitride region 14 in the structure shown in FIG. 2J is then removed. This can be done by either wet etch or anisotropic etch with the polysilicon 12 used as an etch stop. The resultant structure is shown in FIG. 2K.

Using the oxide spacer 18 as a mask, an isotropic etch of the polysilicon 12 is then performed. This is followed by a wet etch of oxide which causes a portion of the oxide spacer 18 to be removed laterally. The resultant structure is shown in FIG. 2L. The polysilicon section 12 is now an isolated floating gate. The floating gate has a “tip” 28, which is at one end of the floating gate 12.

A high temperature thermal oxide deposition process is then performed over the structure shown in FIG. 2L. The result is a deposition of a layer of oxide 30 over the entire structure and the resultant structure is shown in FIG. 2M.

A layer of polysilicon 32 is deposited over the structure shown in FIG. 2M. The layer of polysilicon 32 would eventually form the control gate. The resultant structure is shown in FIG. 2N.

The layer of polysilicon 32 is then subject to an anisotropic etch with the HTO oxide layer 30 as the etch stop. The polysilicon 32 is formed continuously in the X direction and forms the control gate for each of the memory cells. The resultant structure is shown in FIG. 20.

Finally, ion implantation of N type material would be made to form drain regions between the control gates 32. Thereafter bit lines would be formed to connect to the drain regions with the bit lines running in the Y direction.

The problem with the foregoing method of the prior art is in the formation of the tip 28 for the floating gate 12. Particularly, the problem arises in the method of the step shown in FIG. 2L when the polysilicon 12 is anisotropically etched. Ideally, a “perfect” tip 28 is formed when the anisotropic etch is performed along the line 34 as shown in FIG. 2P. However, if the anisotropic cutting of the polysilicon 12 occurs along the line 32, as can be seen in FIG. 2P, no “tip” results. As a result, a memory cell without a tip does not function as well as a memory with a tip 28 during the poly to poly tunneling erase operation. Of course if a cut occurred along the line 36, although a “tip” is formed, it is not as pronounced as the tip formed along line 34.

### SUMMARY OF THE INVENTION

In the present invention, an electrically programmable and erasable memory cell has a semiconductor substrate of a first conductivity type. A first and second spaced apart regions of a second conductivity type are in the substrate. A channel is between the first and second spaced apart regions for the conduction of charges. A floating gate is insulated and spaced apart from the substrate with a floating gate for storing charges and for controlling the conduction of charges in the channel. The floating gate has a tip for ejecting charges therefrom. The floating gate has a length with a first end and a second end with a tip located between the first end and the second end. A control gate is insulated and spaced apart from the substrate and the floating gate.

The present invention also relates to a semiconductor non-volatile memory device having an array of the foregoing described non-volatile memory cells, arranged in a plurality of rows and columns.

Finally, the present invention relates to a method of making a non-volatile memory cell and an array of such non-volatile memory cells having a floating gate with an improved tip as described heretofore.

### BRIEF DESCRIPTION OF THE DRAWINGS

FIG. 1A is a top view of a semiconductor substrate used in the first step of the method of present invention to form isolation regions.

FIG. 1B is a cross sectional view of the structure taken along the line 1B-1B showing the initial processing steps of the present invention.

FIG. 1C is a top view of the structure showing the next step in the processing of the structure of FIG. 1B, in which isolation regions are defined.

FIG. 1D is a cross sectional view of the structure in FIG. 1C taken along the line 1D-1D showing the isolation trenches formed in the structure.

FIG. 1E is a cross sectional view of the structure in FIG. 1D showing the formation of isolation blocks of material in the isolation trenches.

FIGS. 2A-20 are cross-sectional views of the semiconductor structure in FIG. 1E taken along the line 2A-2A showing in sequence the steps of the prior art in the processing of the semiconductor structure in the formation of the cell portion of a non-volatile memory array of floating gate memory cells of the prior art.

FIG. 2P is an enlarged cross-sectional view of a portion of the structure shown in FIG. 2L showing the various possible results using the method of the prior art resulting in a floating gate without a “sharp” tip.

FIGS. 3A-3T are cross-sectional views of a semiconductor structure in FIG. 1E taken along the line 2A-2A showing in sequence the steps in the method of the present invention for processing the semiconductor structure in the formation of the cell portion of a non-volatile memory array of floating gate memory cells of the present invention.

FIG. 3U is an enlarged cross-sectional view of a portion of the structure shown in FIG. 3S showing the various possible results using the method of the present invention wherein a floating gate with a “sharp” tip is formed, even with some mis-alignment in the etching process.

### DETAILED DESCRIPTION OF THE INVENTION

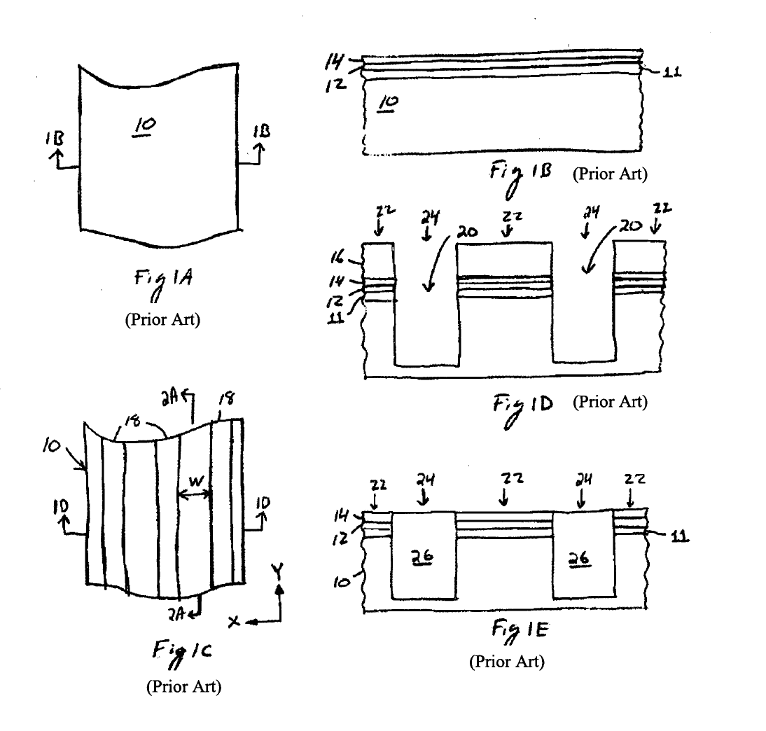

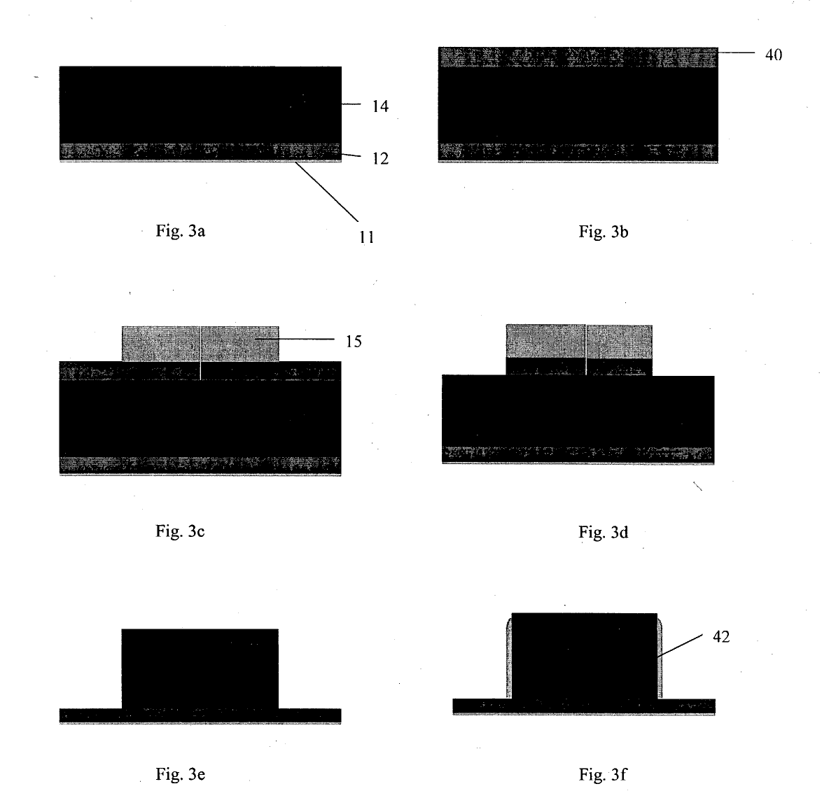

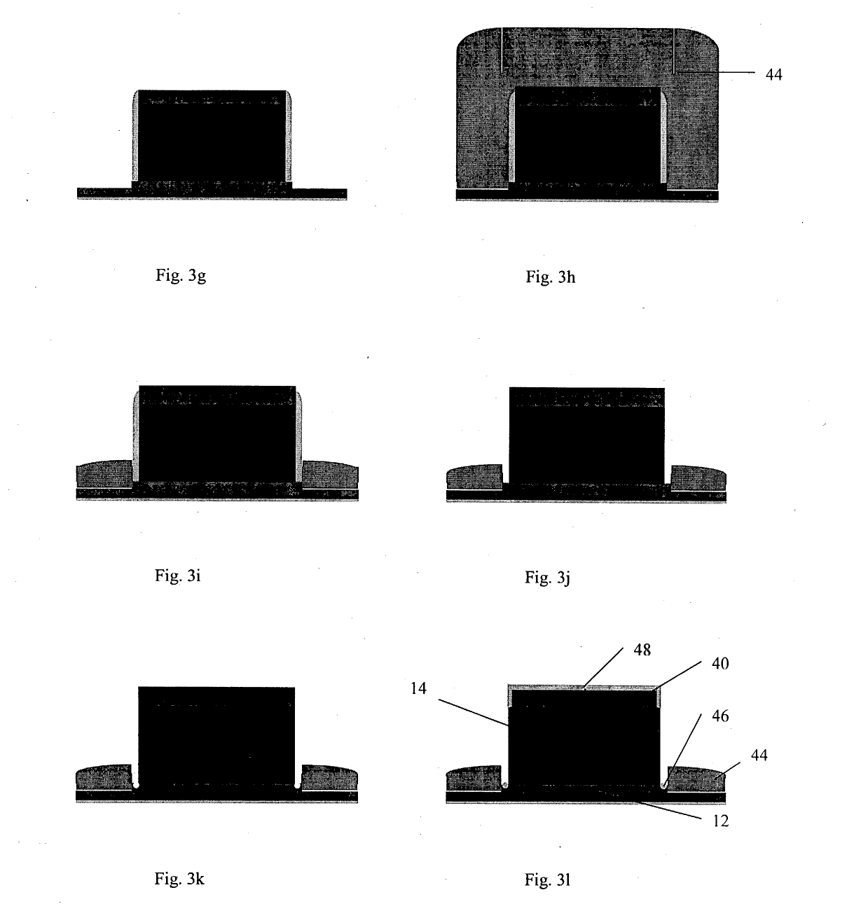

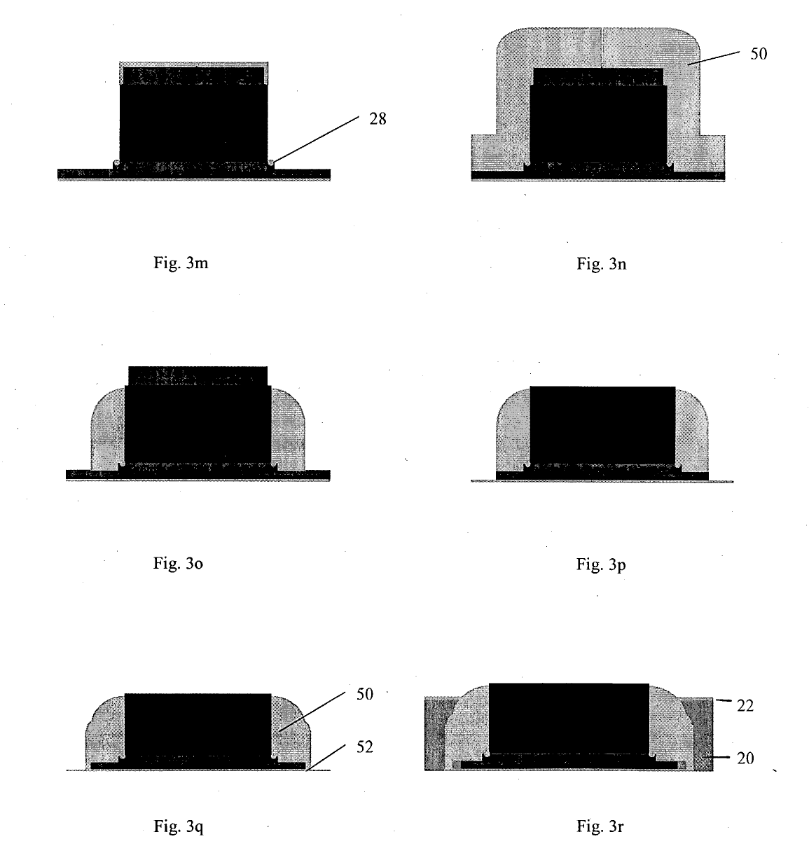

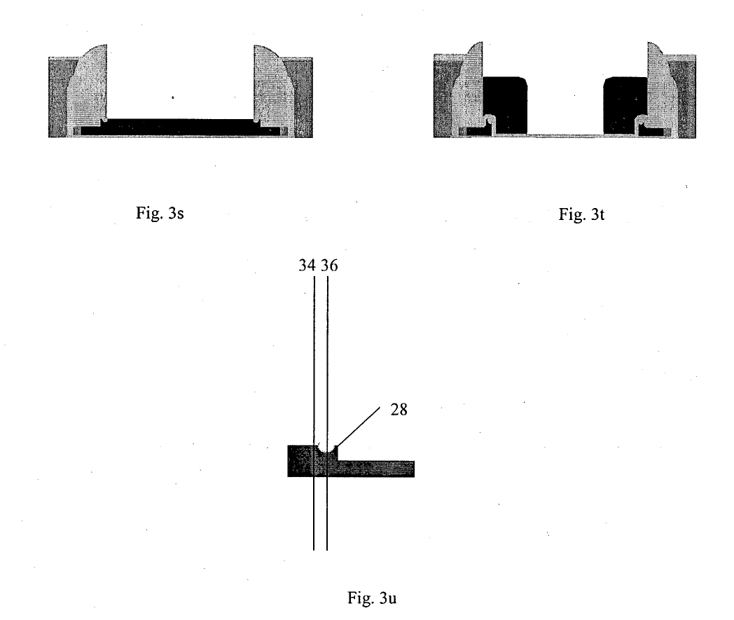

The method of the present invention is illustrated in FIGS. 1A-1E and 3A-3T which show the processing steps of the present invention in making the memory cell and array of the present invention. The steps of making the well known STI isolation regions shown in FIGS. 1A-1E have been previously discussed.

The structure shown in FIG. 1E is further processed as follows. A layer of buffer polysilicon 40 on the order of 1000-2000 angstroms thick is deposited everywhere on the nitride layer 14. This deposition can be done by conventional deposition technique. The resultant structure is shown in FIG. 3B.

Photoresist 15 is then deposited on the polysilicon buffer layer 40 and is then masked and etched. The resultant structure is shown in FIG. 3C.

Using the photoresist 15 as the mask, the buffer polysilicon layer 40 is then anisotropically etched with the nitride layer 14 used as an etch stop. The resultant structure is shown in FIG. 3D.

Using the photoresist 15 and the buffer oxide layer 40 as a mask, the nitride layer 14 is etched anisotropically, with the bottom polysilicon layer 12 used as an etch stop. After the nitride layer 14 has been etched, the photoresist 15 is then removed. The resultant structure is shown in FIG. 3E.

A thin layer of silicon dioxide 42 is deposited on the structure shown in FIG. 3E. The layer of oxide 42 is approximately 200 to 400 angstroms thick. The oxide 42 is then anisotropically etched leaving a thin spacer 42 formed adjacent to the nitride 14 and the buffer polysilicon 40. The resultant structure is shown in FIG. 3F.

Using the oxide spacer 42 as a mask, the polysilicon 12 is partially anisotropically etched. The etch may be isotropic or anisotropic resulting in either a sloped etch or a vertical etch. The resultant structure is shown in FIG. 3G.

A thick layer of silicon nitride 44 is then deposited on the structure shown in FIG. 3G. The layer of silicon nitride 44 is deposited everywhere. The nitride 44 can be deposited by conventional process. The thickness of the silicon nitride is such that it covers at least the space between like structures shown in FIG. 3G. The resultant structure is shown in FIG. 3H.

The structure shown in FIG. 3H is then anisotropically etched for the silicon nitride 44. The silicon nitride 44 is anisotropically etched at least until it no longer “covers” the top portion of the oxide spacer 42, with some silicon nitride left. The resultant structure is shown in FIG. 31.

With the oxide spacer 42 “exposed”, it can now be removed by a wet or dry etch process. The oxide spacer 42 is removed with the polysilicon layer 12 used as an etch stop. The resultant structure is shown in FIG. 3J. As can be seen in FIG. 3J, there is a “gap” between the nitride 44 and the nitride 14.

The structure shown in FIG. 3J is then subject to a wet etch of polysilicon 12. This results in the etching of only the polysilicon 12 that is between the silicon nitride 44 and the silicon nitride 14, since the rest of the polysilicon 12 is covered. The wet etch of the polysilicon 12 creates a “groove”. The resultant structure is shown in FIG. 3K.

The structure shown in FIG. 3K is then subject to an oxidation process. This oxidizes the “top” of the buffer polysilicon 40 forming an oxide cap 48 as well as the polysilicon 12 that is in the “groove” exposed between the silicon nitride 44 and the silicon nitride 14, forming an oxide cover 46. The resultant structure is shown in FIG. 3L.

The structure shown in FIG. 3L is then subject to an anisotropic silicon nitride etch removing the silicon nitride 44 with the polysilicon 12 used as an etch stop. The removal of the silicon nitride 44 shows the tip 28 being formed in the polysilicon 12. The resultant structure is shown in FIG. 3M.

The structure shown in FIG. 3M is then coated by a layer of oxide 50 deposited by the TEOS deposition process. The oxide layer 50 is on the order of 2500 to 4500 angstroms. The resultant structure is shown in FIG. 3N.

The structure shown in FIG. 3N is then subject to an anisotropic etch of the oxide layer 50. The result of an anisotropic etch of the silicon dioxide 50 is the formation of an oxide spacer 50 adjacent to the nitride 14. The cap oxide 48 is removed. The resultant structure is shown in FIG. 30.

The structure shown in FIG. 30 is then subject to an anisotropic polysilicon etch. This removes the buffer polysilicon layer 40. In addition, because it is an anisotropic etch, the oxide spacer 50 is used as a mask to cut the polysilicon layer 12. The resultant structure is shown in FIG. 3P.

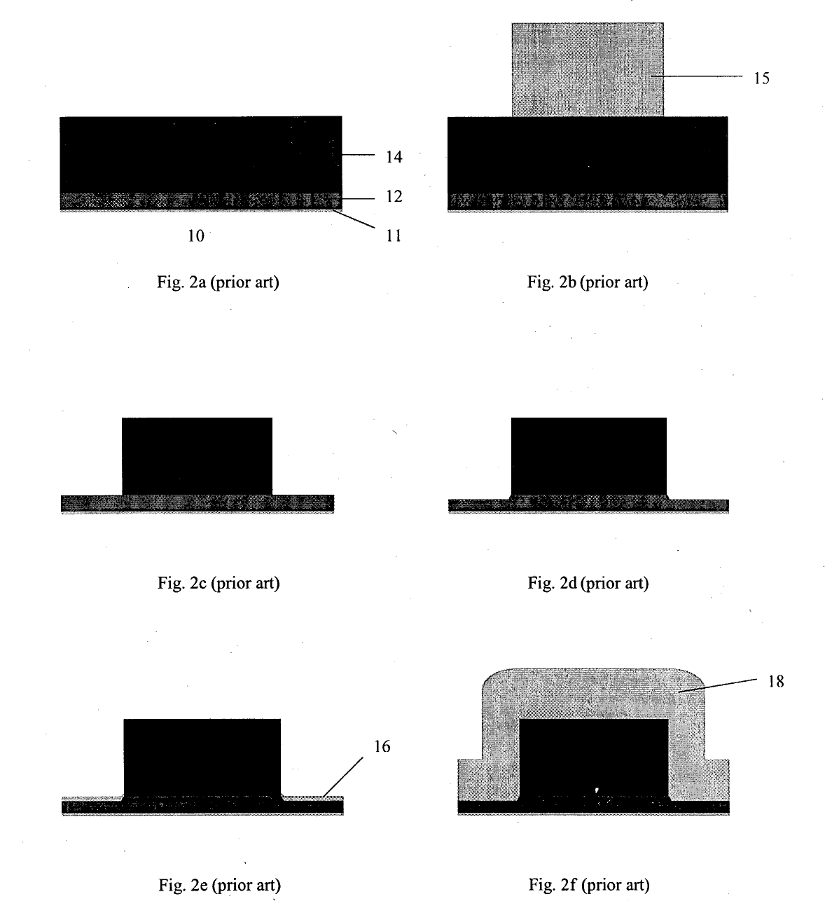

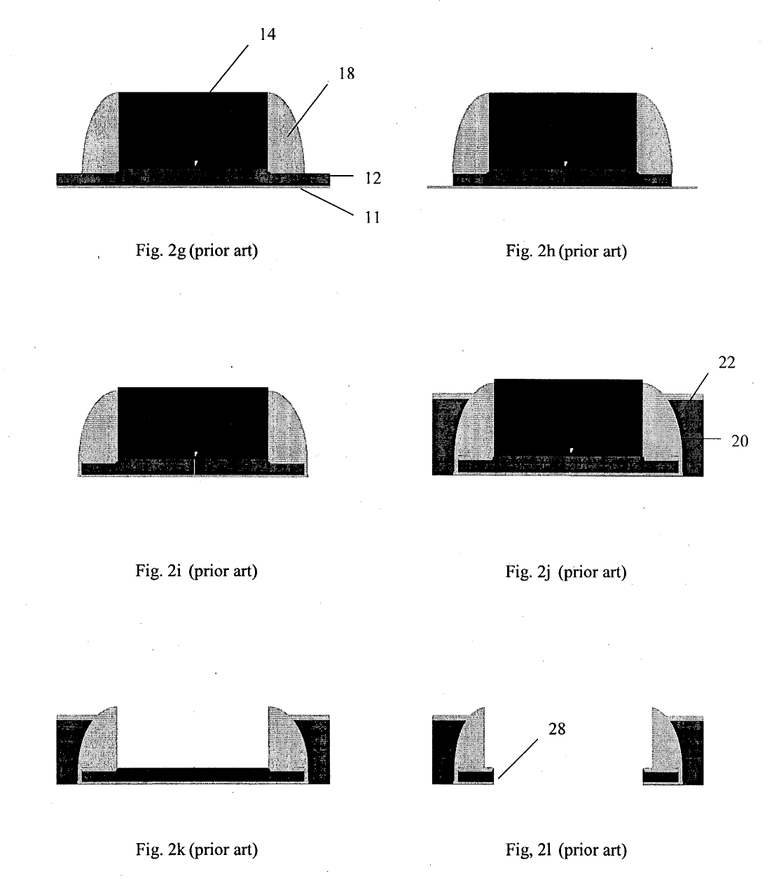

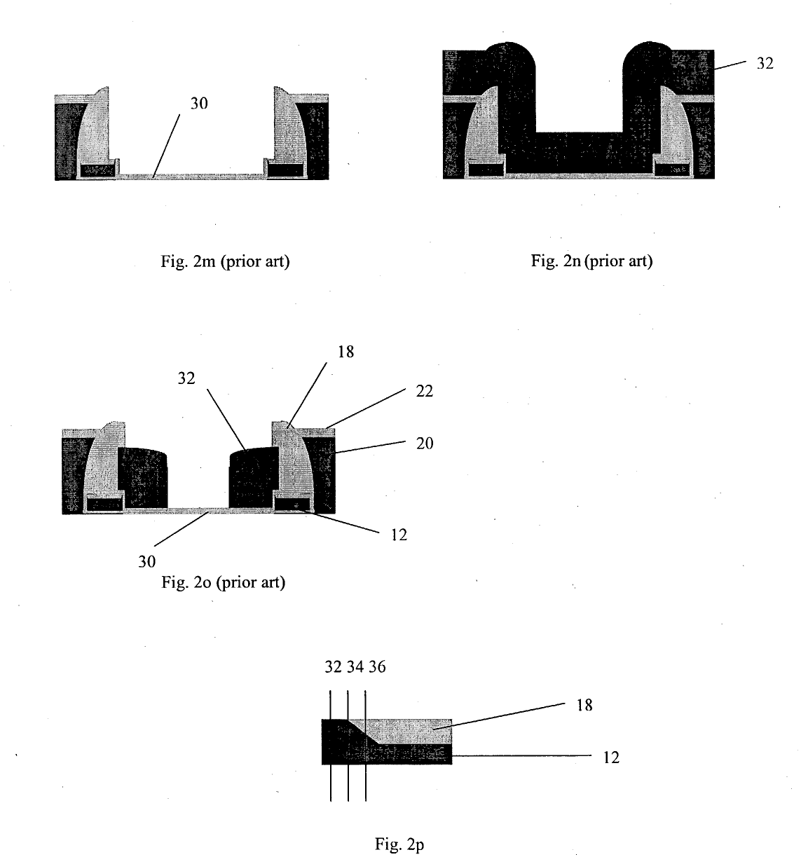

Similar to the process shown in FIG. 2I, a thin layer of oxide, on the order of 200 to 600 angstroms, is deposited everywhere. The oxide layer is then subject to an anisotropic etch resulting in a thin oxide spacer 52 being adjacent to the polysilicon 12 and adjacent to the oxide spacer 50. The thin oxide spacer 52 “protects” the polysilicon 12 and totally insulates it. The resultant structure is shown in FIG. 3Q.

The structure in FIG. 3Q is subject to an anistropic etch of the oxide layer 11 until the substrate 10 is reached. This removes the oxide layer 11 from regions between the thin oxide spacer 52. Similar to the process shown in FIG. 2J, implantation can be made to form source regions in the substrate 10. This is then followed by a deposition of polysilicon 20 which makes contact with the implanted source region in the substrate 10. The polysilicon 20 is then subject to an anisotropic etch to a level such that the oxide spacer 50 is exposed. The polysilicon 20 is also oxidized forming the oxide 22. The resultant structure is shown in FIG. 3R.

The structure shown in FIG. 3R is then subject to a nitride etch, either wet or dry, and the nitride 14 is removed. The resultant structure is shown in FIG. 3S.

From the structure shown in FIG. 3S, the steps of anisotropically etching the polysilicon 12, the etched back of the oxide spacer 50, and the formation of the control gate 32 all similar to the process disclosed and shown in FIGS. 2L, 2M, and 2N are performed. The resultant structure is shown in FIG. 3T. Thereafter the formation of the drain and contacts to the drain would be the same as the method of the prior art.

The advantage of the method of the present invention can be seen with reference to FIG. 3u which is an enlarged cross-sectional view of a portion of the structure shown in FIG. 3s, prior to the structure being subject to a polysilicon anisotropic etch. Line 34 is the cut if there were perfect alignment in the anisotropic etching process. As can be seen, if the anisotropic etch were made along line 34, the tip 28 remains unchanged. Further, even if there is mis-alignment in the anisotropic etch, such as to line 36, the tip 28 still remains. Therefore, because the tip is not formed at one of the “ends” of the polysilicon 12, the tip is immune to mis-aligment in the etching process. Thus, with the method of the present invention, a non-volatile memory cell will have an injector “tip” even if there is process mis-alignment.

1. An electrically programmable and erasable memory cell having:
a semiconductor substrate of a first conductivity type;
first and second spaced apart regions of a second conductivity type in said substrate, with a channel therebetween for the conduction of charges;
a floating gate insulated and spaced apart from said substrate; said floating gate for storing charges and for controlling the conduction of charges in said channel, said floating gate having a tip for ejecting charges therefrom;
a control gate insulated and spaced apart from said substrate and said floating gate;
wherein said improvement comprising:
said floating gate having a length with a first end having a first edge and a second end having a second edge with said tip located spaced apart from said first edge and said second edge.

2. The cell of claim 1 wherein said control gate is positioned adjacent to said floating gate and adapted to receive charges ejected from said tip.

3. The cell of claim 2 wherein said control gate is adjacent to said floating gate and is separated by a first insulating layer for permitting Fowler-Nordheim tunneling therebetween.

4. The cell of claim 3 wherein said floating gate is further insulated and capacitively coupled to said first region.

5. The cell of claim 4 wherein said floating gate is separated from said substrate by a second insulating layer for permitting hot channel injection of electrons from said substrate to said floating gate.

6. The cell of claim 5 wherein said channel has a first portion and a second portion with said first portion adjacent to said first region and said second portion adjacent to said second region, wherein said control gate is insulated and spaced apart from said second portion for controlling the conduction of said charges in said second portion.

7. An electrically programmable and erasable memory cell comprising:
a semiconductor substrate of a first conductivity type;
a first region of a second conductivity type in said substrate;
a second region of a second conductivity type in said substrate, spaced apart from said first region;
a channel between said first region and said second region for the conduction of charges therebetween, said channel having a first portion adjacent to said first region and a second portion adjacent to said second region;
a first insulation layer on said substrate;
a floating gate on said first insulation layer and spaced apart from said first portion, said floating gate capacitively coupled to said first region; said floating gate having a length in said channel direction with a first end with a first edge and a second end with a second edge, with a tip located spaced apart from said first edge-and said second edge; and
a control gate on said first insulation layer and spaced apart from said second portion, said control gate insulated and spaced apart from said floating gate by a second insulation layer; said control gate having a portion aligned with said tip.

8. The cell of claim 7 wherein said second insulation layer permitting Fowler-Nordheim tunneling of charges from said tip of said floating gate to said control gate.

9. The cell of claim 8 wherein said first insulation layer for permitting hot channel injection of electrons from said substrate to said floating gate.

10. The cell of claim 7 wherein said tip projects in a direction substantially perpendicular to said channel direction.

11. A semiconductor non-volatile memory device comprising:
a semiconductor substrate of a first conductivity type;
an array of non-volatile memory cells arranged in a plurality of rows and columns on said substrate, wherein each memory cell comprises:
a first region of a second conductivity type in said substrate;
a second region of a second conductivity type in said substrate, spaced apart from said first region;
a channel between said first region and said second region for conducting charges therebetween;
a floating gate insulated and spaced apart from said substrate for controlling the conduction of charges in said channel, said floating gate having a length with a first end with a first edge and a second end with a second edge with a tip located between said first edge and said second edge;
a control gate insulated and spaced apart from said substrate and said floating gate, and positioned to receive charges ejected through said tip from said floating gate;
wherein cells in the same column have said first region connected in common;
wherein cells in the same row have said control gate connected in common; and
wherein cells in the same row have said second region connected in common.

12. The device of claim 11:
a first insulation layer between said substrate and said floating gate;
a second insulation layer, between said tip and said control gate;
wherein said second insulation layer permitting Fowler-Nordheim tunneling of charges from said tip to said control gate.

13. The device of claim 12 wherein said first insulation layer permitting hot channel injection of electrons from said substrate to said floating gate.

14. The device of claim 13 wherein said tip projects in a direction substantially perpendicular to said channel.

15. The device of claim 14 wherein said floating gate is capacitively coupled to said second region.

16. The device of claim 15 wherein said channel has a first portion and a second portion, with said first portion adjacent to said first region and said second portion adjacent to said second region, with said floating gate positioned to control conduction of charges in said second portion.

17. The device of claim 16 wherein said control gate has a portion positioned adjacent to said floating gate and for controlling the conduction of charges in said first portion.

18-27 (Cancelled)
